(19) United States
(12) Patent Application Publication
(10) Pub. No.: US 2016/0349710 A1
(43) Pub. Date: Dec. 1, 2016

(54) SUNSCREEN REAPPLICATION REMINDER DEVICE AND METHOD

(71) Applicant: George A. Downey, Arlington, MA (US)

(72) Inventor: George A. Downey, Arlington, MA (US)

(21) Appl. No.: 14/722,052

(22) Filed: May 26, 2015

(51) Int. Cl. G04F 3/06; H01H 13/86; A45D 40/00; G08B 3/10; G08B 5/22; H05K 5/06; G08B 21/24

(52) U.S. Cl. CPC G04F 3/06; H05K 5/06; H01H 13/86; G08B 21/24; G08B 3/10; G08B 5/22; A45D 40/00; A45D 2200/05

(57) ABSTRACT

In one general aspect, an apparatus for managing exposure to the sun is disclosed. It includes an aquatic activity control responsive to user interaction and an aquatic activity indicator associated with the aquatic activity control and operative to identify the aquatic activity control. It also includes a terrestrial activity control responsive to user interaction and a terrestrial activity indicator associated with the terrestrial activity control and operative to identify the terrestrial activity control. Timer logic is responsive to the aquatic activity control and the terrestrial activity control and it is operative to measure different predetermined sunscreen-product-specific time durations for a predetermined sunscreen product corresponding to sunlight exposure limits for aquatic or terrestrial activities in response to respective actuation of the aquatic activity control or the terrestrial activity control. An alert transducer is responsive to the timer logic, and a water-resistant housing is provided for at least part of the aquatic activity control, the terrestrial activity control, and the timer logic.

### CROSS-REFERENCE TO RELATED APPLICATION

This application is a continuation of application Ser. No. 14/273,117, filed May 8, 2014, which is a continuation of application Ser. No. 14/048,029, filed Oct. 7, 2013, which are both herein incorporated by reference.

### FIELD OF THE INVENTION

The present invention relates to sun care, including devices and methods to remind users to reapply sunscreen at appropriate intervals.

### BACKGROUND OF THE INVENTION

Skin exposure to UV radiation from the sun or other source can be harmful. Even short term exposure may lead to skin-damaging sunburns. Frequent and extended exposure can lead to the development of skin cancers and premature aging and/or marking of the skin. Research also suggests that such exposures at a young age may increase these risks appreciably. Sunscreens have been developed to protect the skin from harmful UV rays or by absorbing or reflecting UV radiation, or a combination of both. But the effectiveness of sunscreens diminishes over time at a rate that can depend on use conditions, such as when swimming.

Reapplication of sunscreen can therefore be important in helping to maintain effective skin protection against UV rays from the sun or other source. Sunscreen manufactures and recognized bodies in the health care industry provide literature and/or labeling information for sunscreen protection, which lists effective protection time and importance of sunscreen reapplication, but this material effectively leaves it up to the user to remember to reapply sunscreen at the required time.

Web applications for portable devices are currently available that can be worn by a user or put on nearby objects so that they can alert the user when it is time to reapply a sunscreen. But these devices tend to be expensive and vulnerable to damage during outdoor activities where sun exposure protection would be necessary. Watches and timers that can be carried or clipped to bags and other objects can be forgotten, misplaced, or lost, rendering them ineffective. They can also be complex and cumbersome to program, and can potentially be programmed incorrectly.

### SUMMARY OF THE INVENTION

In one general aspect, the invention features an apparatus for managing exposure to the sun. It includes an aquatic activity control responsive to user interaction and an aquatic activity indicator associated with the aquatic activity control and operative to identify the aquatic activity control. It also includes a terrestrial activity control responsive to user interaction and a terrestrial activity indicator associated with the terrestrial activity control and operative to identify the terrestrial activity control. Timer logic is responsive to the aquatic activity control and the terrestrial activity control and it is operative to measure different predetermined sunscreen-product-specific time durations for a predetermined sunscreen product corresponding to sunlight exposure limits for aquatic or terrestrial activities in response to respective actuation of the aquatic activity control or the terrestrial activity control. An alert transducer is responsive to the timer logic, and a water-resistant housing is provided for at least part of the aquatic activity control, the terrestrial activity control, and the timer logic.

In preferred embodiments the aquatic activity control and the terrestrial activity control can both include push-buttons. The alert transducer can include an alphanumeric display. The alert transducer can include a sounder. A count-down timer display can be responsive to the timing logic. A clock display can be responsive to the timing logic. The apparatus can further include a vessel for holding the product. The vessel and the housing can be integral. The apparatus can further include a removable mounting mechanism for mounting the housing to the vessel. The removable mounting mechanism can employ one of a pocket, a clip, a tether, or hook-and-loop fastener. The indicators can be alphanumeric. The indicators can be graphical. The apparatus can further include a factory-settable product selection control. The housing can be configured specifically to interface with a particular predetermined feature or feature set of a sunscreen vessel. The timer logic can be responsive to the aquatic activity control to initiate a time duration of at about 80 minutes and the timer logic is responsive to the terrestrial activity control to initiate a time duration of at about 2 hours. The aquatic activity control and the terrestrial activity control can be separated by the alert transducer to help avoid inadvertent selection of an unintended time interval. The apparatus can further include a user-facing product identification on the housing that identifies the predetermined product.

In another general aspect, the invention features an apparatus for managing exposure to the sun that includes means responsive to user interaction for selecting a first activity type, means for identifying the means for selecting a first activity type, means responsive to user interaction for selecting a second activity type, means for identifying the means for selecting a second activity type, means for timing a first sunshine exposure duration associated with the first activity type, means for timing a second sunshine exposure duration different from the first sunshine exposure duration and associated with the second activity type, and means responsive to the first means for timing a first sunshine exposure and to the means for timing a second sunshine exposure, for alerting the user at the end of the first and second durations.

In a further general aspect, the invention features a method for managing exposure to the sun that includes providing a vessel for a sunscreen product, providing a sunscreen product in the vessel having a plurality of sunscreen-product-specific time durations corresponding to sunlight exposure limits for different types of activities, providing timing logic associated with the vessel and having a predetermined duration corresponding to the sunscreen-product-specific time durations of the sunscreen product in the vessel, applying the sunscreen to an area of the skin, starting the timing logic for a first type of activity, providing a first timing indication from the timing logic for the first type of activity, again applying the sunscreen to an area of the skin after the step of providing, starting the timing logic for a second type of activity, providing a second timing indication from the timing logic for the second type of activity, and again applying the sunscreen to an area of the skin after the step of providing a second timing indication.

In preferred embodiments the steps of starting and providing for a first type of activity can be for a terrestrial activity and the steps of starting and providing for a second type of activity can be for an aquatic activity. The steps of providing a sunscreen product and providing timing logic can be performed by different commercial entities. The method can further include the step of configuring the timing logic for the sunscreen product provided in the step of providing a sunscreen product. The step of providing timing logic can include an end-user selection among different timer models.

Devices and methods according to the invention can provide simple, reliable, and effective sunscreen reapplication reminders, which can help to reduce exposure to hazardous levels of UV radiation. Closely integrating such devices to sunscreen containers and the product they contain allows devices and methods according to the invention to help to ensure that they are not forgotten or used with the wrong product. And their simple design can help to ensure that they are used consistently and correctly without saddling the user with a substantial cost.

### BRIEF DESCRIPTION OF THE DRAWING

FIG. 1A shows a plan view of a sunscreen reapplication reminder unit according to the invention for mounting on a sunscreen vessel, such as a tube,

FIG. 1B shows a plan view of a device comprising a sunscreen vessel equipped with the sunscreen reapplication reminder unit of FIG. 1A,

FIG. 1C shows a side view of the device of FIG. 1B,

FIG. 2A shows a perspective view of an embodiment of a device that includes a sunscreen wipe container equipped with a sunscreen reapplication reminder unit, such as the one shown in FIG. 1A,

FIG. 2B shows a perspective view of an embodiment of a device that includes a sunscreen squeeze tube equipped with a sunscreen reapplication reminder unit, such as the one shown in FIG. 1A,

FIG. 2C shows a perspective view of an embodiment of a device that includes a sunscreen vessel with a flip-top equipped with a sunscreen reapplication reminder unit, such as the one shown in FIG. 1A,

FIG. 2D shows a perspective view of an embodiment of a device that includes a sunscreen spray bottle equipped with a sunscreen reapplication reminder unit, such as the one shown in FIG. 1A,

FIG. 2E shows a perspective view of an embodiment of a device that includes an irregularly shaped sunscreen vessel equipped with a sunscreen reapplication reminder unit, such as the one shown in FIG. 1A,

FIG. 3A shows an exploded view of one possible implementation of a device that includes the sunscreen reapplication reminder unit of FIG. 1A, identifying the components of the unit,

FIG. 3B shows a perspective view of the implementation of FIG. 3A,

FIG. 3C shows a sectional view taken along line A-A in FIG. 3A,

FIG. 3D shows a partial sectional view of a screw-based version of the implementation of FIG. 3A, taken along line A-A in FIG. 3A,

FIG. 3E shows a partial sectional view of a snap-joint-based version of the implementation of FIG. 3A, taken along line A-A in FIG. 3A,

FIG. 3F shows a partial sectional view of a welded version of the implementation of FIG. 3A, taken along line A-A in FIG. 3A,

FIG. 4A shows a plan view of one implementation of the sunscreen reapplication reminder unit of FIG. 1A that employs an analog countdown display,

FIG. 4B shows a plan view of one implementation of the sunscreen reapplication reminder unit of FIG. 1A that employs a light-based countdown display,

FIG. 5A and 5B show respective plan and side views of an embodiment of a device that includes a sunscreen tube equipped with a sunscreen reapplication reminder unit, such as the one shown in FIG. 1A, held in place in a pocket,

FIG. 5C and 5D show respective plan and side views of an embodiment of a device that includes a sunscreen tube equipped with a sunscreen reapplication reminder unit, such as the one shown in FIG. 1A, held in place by lamination,

FIG. 5E and 5F show respective plan and side views of an embodiment of a device that includes a sunscreen tube equipped with a sunscreen reapplication reminder unit, such as the one shown in FIG. 1A, held in place by an elastic or hook-and loop fastener,

FIG. 5G and 5H show respective plan and side views of an embodiment of a device that includes a sunscreen tube equipped with a sunscreen reapplication reminder unit, such as the one shown in FIG. 1A, held in place by an adhesive,

FIG. 5I shows plan and side views of an embodiment of a device that includes a sunscreen tube equipped with a sunscreen reapplication reminder unit, such as the one shown in FIG. 1A, held in place in place by a string or ribbon,

FIG. 5J and 5K show respective plan and side views of an embodiment of a device that includes a sunscreen tube equipped with a sunscreen reapplication reminder unit, such as the one shown in FIG. 1A, held in place by welding,

FIG. 5L and 5M show respective plan and side views of an embodiment of a device that includes a sunscreen tube equipped with a sunscreen reapplication reminder unit, such as the one shown in FIG. 1A, held in place by virtue of its being included in a clip that matches the profile of an end weld in the tube,

FIG. 5N and 5O show respective plan and side views of an embodiment of a device that includes a sunscreen tube equipped with a sunscreen reapplication reminder unit, such as the one shown in FIG. 1A, held in place by a buckled belt,

FIG. 5P shows a perspective view of an embodiment of a device that includes a sunscreen cozy equipped with a sunscreen reapplication reminder unit, such as the one shown in FIG. 1A, and

FIG. 5Q and 5R show respective open and closed views an embodiment of a device that includes a sunscreen tube cap equipped with a sunscreen reapplication reminder unit, such as the one shown in FIG. 1A, in a manner similar to those shown to equip the unit to a vessel.

### DETAILED DESCRIPTION OF AN ILLUSTRATIVE EMBODIMENT

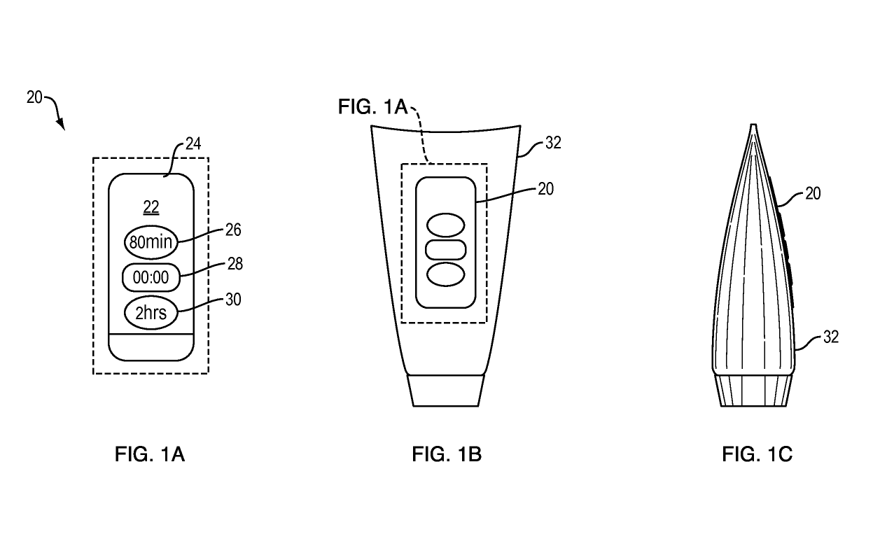

Referring to FIG. 1A-1C, an illustrative sunscreen reapplication reminder unit 20 according to the invention is equipped with provisions, such as on its back surface or perimeter, that permit integration with a sunscreen vessel 32. It includes a user-facing surface 22 that can include a logo area 24, a first identified initiation control 26 (e.g., for swimming), a display 28 (e.g., an LCD display), and a second identified initiation control 30 (e.g., for out-of-the-water activities). In this embodiment, the controls are single-actuation pushbuttons that are sufficiently large to be legibly labeled with alphanumeric labels that sate the different durations that they correspond to. But different types of controls, such as touch sensors, and different types of labeling, such as colors, icons, or images could also be employed. Moreover, the organization of the parts of the device need not be exactly as shown. Preferably, the display shows time intervals in hours and minutes to gauge exposure, and is also able to show the time of day.

The reapplication reminder unit is preferably integrated to a vessel of a product and programmed to provide durations specific to that product and its application method (e.g., spray, liquid, wipe), and may even bear a logo or other product identification for that product. To this end it can be permanently connected or connectable to the product vessel, or it may be configured specifically to interface with a particular predetermined feature or feature set of the vessel.

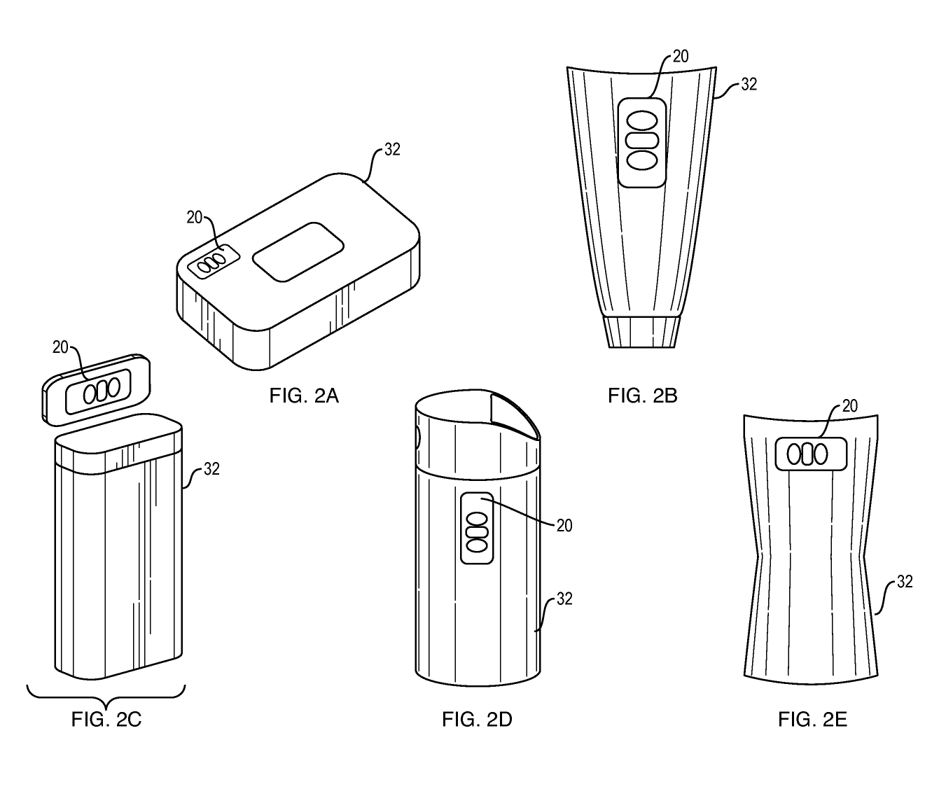

Referring also to FIGS. 2A-2E, the sunscreen reapplication reminder unit 20 can be integrated with a variety of different types of sunscreen vessels. These types can include a sunscreen wipes container (FIG. 2A), a squeeze tube (FIG. 2B), a flip top tube or bottle (FIG. 2C), a spray bottle (FIG. 2D), or an irregularly shaped container (FIG. 2E). While the sunscreen reapplication reminder unit is shown in presently preferred locations, they can be positioned anywhere on the device. It will also be apparent that other types of vessels can be equipped with an integrated sunscreen reapplication reminder unit without departing from the scope or spirit of the invention.

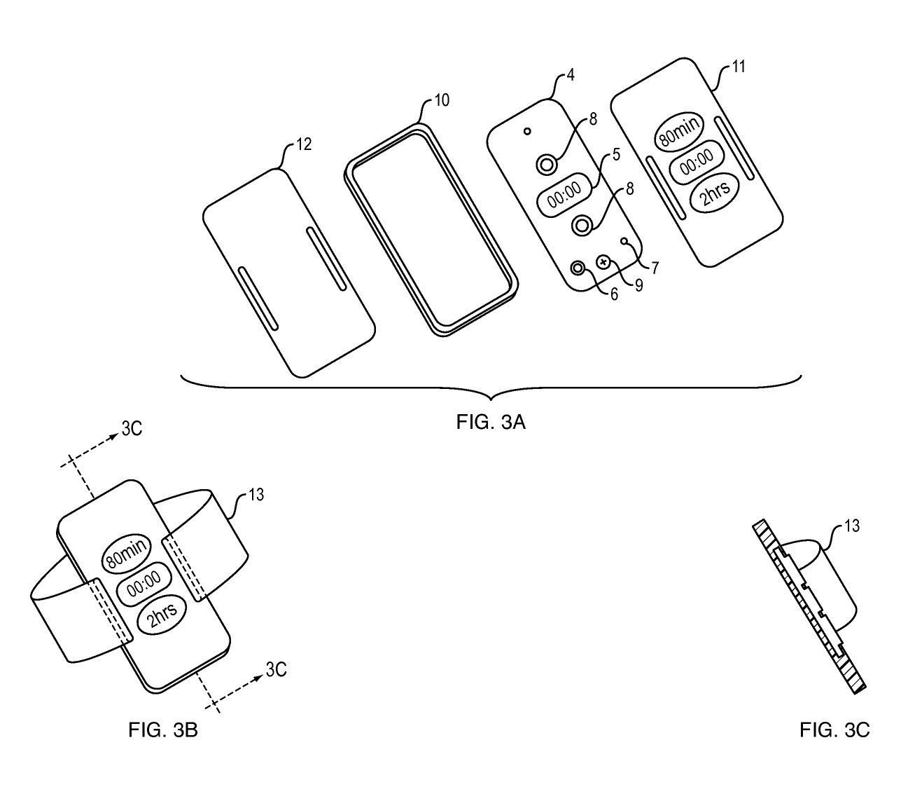

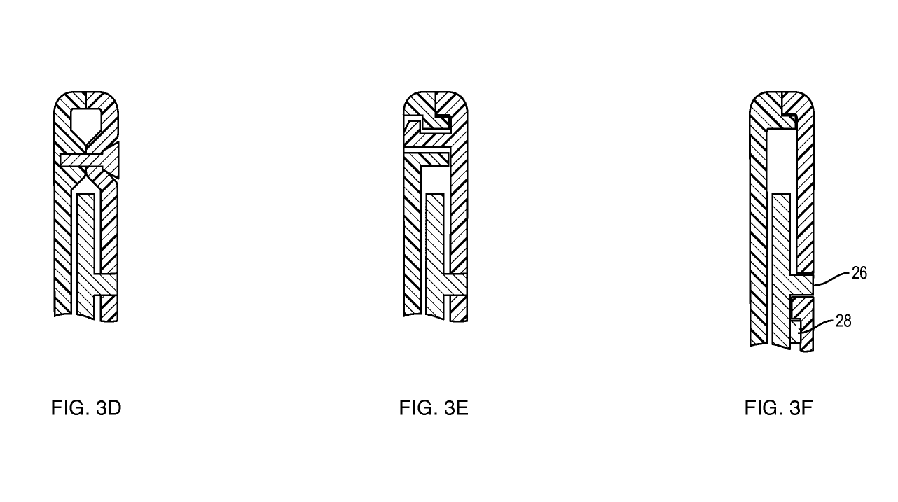

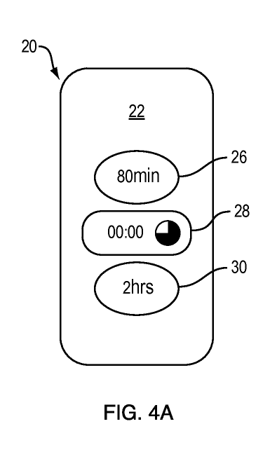

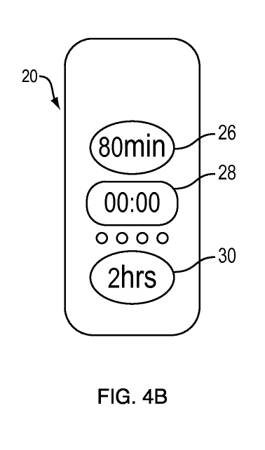

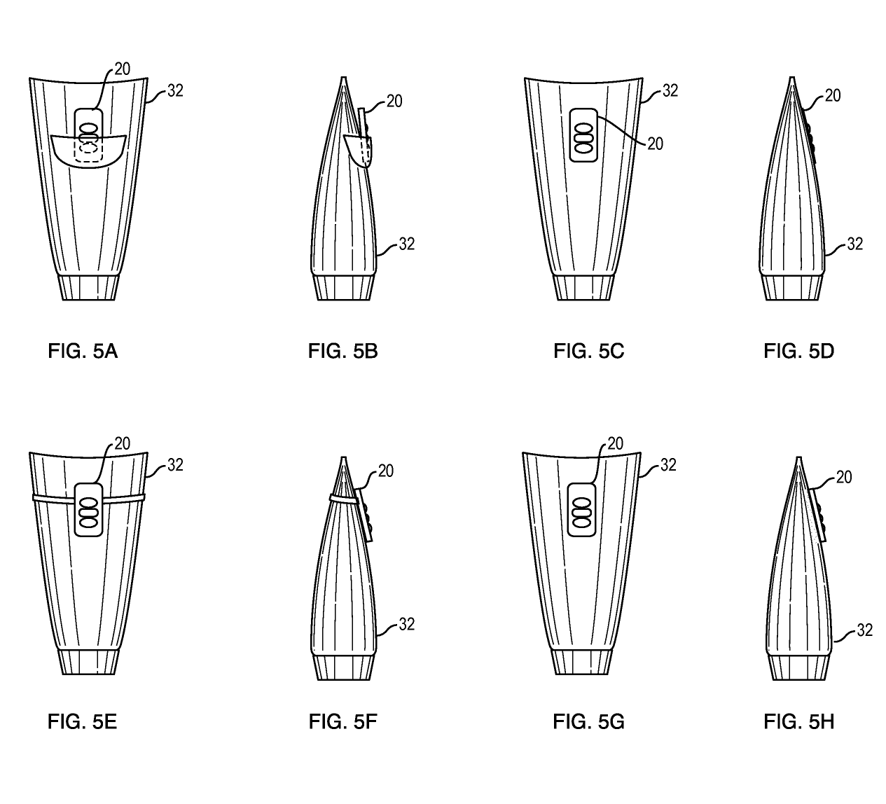

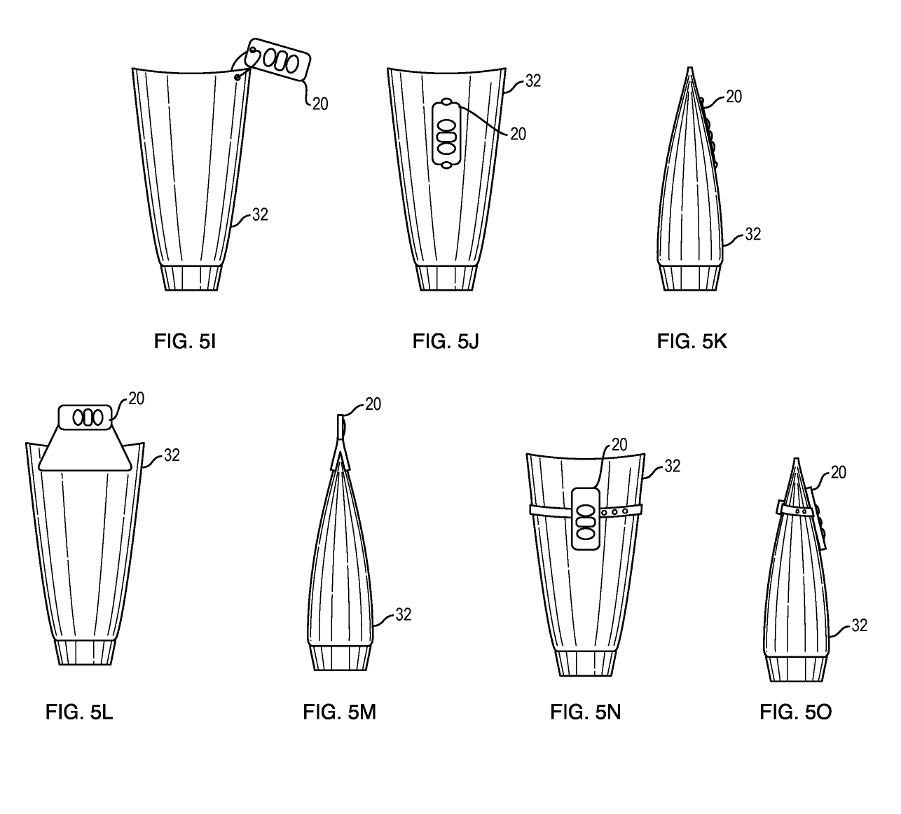

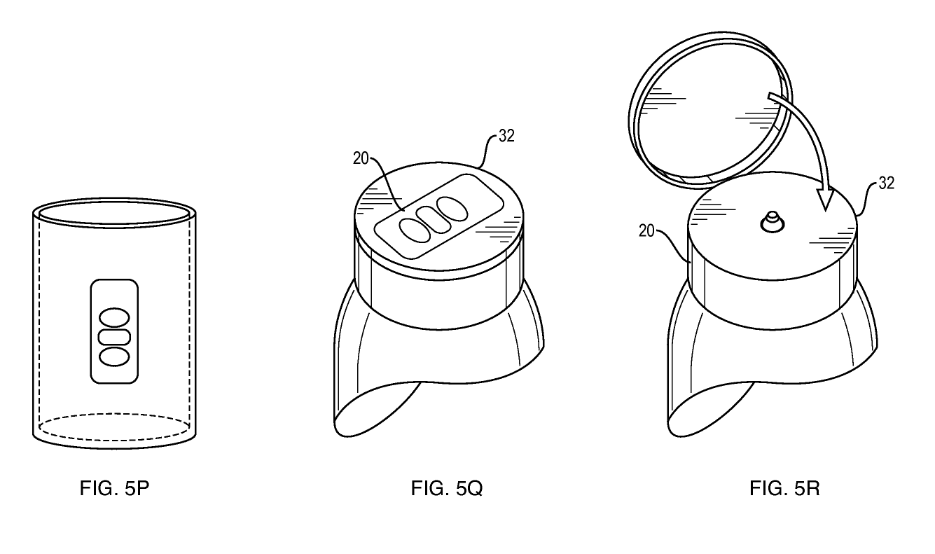

Referring to FIG. 3A, the illustrated sunscreen reapplication reminder unit 20 can include an overlay or casing that has as a top (11) and bottom (12) with appropriate integration features (15) such as a strap (13). The unit is sealed from the elements with a compressible seal (10) or welded casing (14) to protect the unit against handling during intended use. Enclosed within the casing is a PCB assembly (4) that contains the display (5), speaker (6), timing electronics (7), push switches (8), battery (9) and associated circuitry for the function of the device. As shown in FIGS. 3D-F, the device can be assembled in a variety of ways such as using screw joints (FIG. 3D) or snap joints (FIG. 3E), or by welding (FIG. 3F), and it is generally important that the device be substantially sand, sun, and water resistant. While this type of construction is presently preferred, it will be apparent that the specific construction of the sunscreen reapplication reminder unit can vary significantly without departing from the scope or spirit of the invention.

In operation, a user applies a sunscreen product to the skin to be protected and selects the preset time interval on the sunscreen reminder that is integral to that sunscreen vessel. When the interval is complete the user is sent a signal to remind them to reapply the sunscreen. The user can simply press one of the buttons and the sunscreen duration for the selected activity type begins. The durations preferably match the recommended durations for the product in the vessel to which the timer is coupled. This can eliminate the need for user preparation or programming the device prior to use, and human errors in programming the time intervals. In one embodiment, a small product selection control, such as a dip switch or a jumper, can be used to select a predefined set of durations for a particular product. This switch is designed for one-time or occasional use, and may only be accessible during manufacturing.

The preprogrammed selection buttons are convenient and can eliminate the use of any type of “Start” button or the like (i.e. the selection begins the cycle) helping to make it effortless for first time use by the user. This concept can be furthered by having large easy-to-read time intervals marked on top of the buttons that make selection easy and requires little cognitive demand on the user. The buttons can be located on opposite sides of the display to aid in button selection and help address the potential for hitting the wrong button.

During the interval, a countdown indication may be displayed to show the user at least generally when the product will need to be reapplied. When the predetermined exposure duration has expired, visual (e.g., flashing light), auditory (e.g., beep), and/or tactile (e.g., vibrations) reminder signals will begin. Some or all of these may be issued in different patterns. In one embodiment, the unit beeps briefly and a LED flashes for a longer period. In other embodiments, the unit can beep intermittently until cleared. In still further embodiments, one or more lights, such as LEDs, allow a visual indication to the user or those associated with the user that the reminder interval time has completed and reapplication of the sunscreen product in needed. This could be in the form of a solid color or blinking of one or more colors. The LED light(s) could also turn on or change colors as the time approaches completion; from green, to yellow, to red, for example. Many other different types of reminder signals are of course also be possible. In one embodiment, the countdown time and time alternate intermittently on the display.

In one type of embodiment, referring to FIGS. 1 and 3, steps can be taken to construct the sunscreen reapplication reminder unit 20 in such a way that it mates closely with a surface of the outside or inside of the vessel 32 with which it is associated. To this end, it can be manufactured in a low-profile housing that preferably has a thickness of less than about ½ inch, more preferably less than about ¼ inch, or even more preferably less than about ⅛ inch. The sunscreen reapplication reminder unit can also be flexible so that it follows the contour of one or more vessels to which it can be associated. This can be accomplished by manufacturing the sunscreen reapplication reminder unit with a flexible housing and optionally also a flexible circuit board.

The sunscreen reapplication reminder unit 20 can also include expiration detection logic. This can be provided in a variety of ways. Where the reminder unit is sold integral to a vessel that is filled with a sunscreen product, a predetermined expiration date reminder can be programmed into the reminder unit. The expiration date can also be entered in a variety of other ways using controls on the unit, such as by manually entering a date or entering a product name, product ID, or product barcode number from a sunscreen product. The reminder unit can indicate that the expiration date has been reached in different ways, such as by displaying an error message on the display 28 and/or by ceasing to function. In some embodiments, the expiration detection logic may even cause the unit to disable access to the product, such as by blocking a nozzle or spray button with a fused link or solenoid valve. The expiration detection logic can help to avoid the risk of sunburn that can result from using expired sunscreen.

The sunscreen reapplication reminder unit 20 can also be equipped with low battery interlock logic. This logic monitors the battery level to determine if there is sufficient battery life to issue a reminder. If it detects an insufficient level, it can issue a warning on the display and/or refuse to operate. It may even disable access to the product until the battery is replaced. The expiration detection logic and low battery interlock logic can be implemented as part of the same circuitry that provides the reapplication reminder unit's reminder functions. This circuitry can be based on a programmed general-purpose microcontroller and/or dedicated custom circuitry.

The present invention has now been described in connection with a number of specific embodiments thereof. However, numerous modifications which are contemplated as falling within the scope of the present invention should now be apparent to those skilled in the art. Therefore, it is intended that the scope of the present invention be limited only by the scope of the claims appended hereto. In addition, the order of presentation of the claims should not be construed to limit the scope of any particular term in the claims.

What is claimed is:

1. An apparatus for managing exposure to the sun, comprising:
an aquatic activity control responsive to user interaction,
an aquatic activity indicator associated with the aquatic activity control and operative to identify the aquatic activity control,
a terrestrial activity control responsive to user interaction,
a terrestrial activity indicator associated with the terrestrial activity control and operative to identify the terrestrial activity control,
timer logic responsive to the aquatic activity control and the terrestrial activity control and being operative to measure different predetermined sunscreen-product-specific time durations for a predetermined sunscreen product corresponding to sunlight exposure limits for aquatic or terrestrial activities in response to respective actuation of the aquatic activity control or the terrestrial activity control,
an alert transducer responsive to the timer logic, and
water-resistant housing for at least part of the aquatic activity control, the terrestrial activity control, and the timer logic.

2. The apparatus of 1 wherein the aquatic activity control and the terrestrial activity control both include push-buttons.

3. The apparatus of claim 1 wherein the alert transducer includes an alphanumeric display.

4. The apparatus of claim 1 wherein the alert transducer includes a sounder.

5. The apparatus of claim 1 further including a count-down timer display responsive to the timing logic.

6. The apparatus of claim 1 further including a clock display responsive to the timing logic.

7. The apparatus of claim 1 further including a vessel for holding the product.

8. The apparatus of claim 1 wherein the vessel and the housing are integral.

9. The apparatus of claim 1 further including a removable mounting mechanism for mounting the housing to the vessel.

10. The apparatus of claim 9 wherein the removable mounting mechanism employs one of a pocket, a clip, a tether, or hook-and-loop fastener.

11. The apparatus of claim 1 wherein the indicators are alphanumeric.

12. The apparatus of claim 1 wherein the indicators are graphical.

13. The apparatus of claim 1 further including a factory-settable product selection control.

14. The apparatus of claim 1 wherein the housing is configured specifically to interface with a particular predetermined feature or feature set of a sunscreen vessel.

15. The apparatus of claim 1 wherein the timer logic is responsive to the aquatic activity control to initiate a time duration of at about 80 minutes and the timer logic is responsive to the terrestrial activity control to initiate a time duration of at about 2 hours.

16. The apparatus of claim 1 wherein the aquatic activity control and the terrestrial activity control are separated by the alert transducer to help avoid inadvertent selection of an unintended time interval.

17. The apparatus of claim 1 further including a user-facing product identification on the housing that identifies the predetermined product.

18. The apparatus of claim 1 wherein the water-resistant housing is flexible.

19. The apparatus of claim 1 further including sunscreen product expiration detection logic operative to indicate expiration of a predetermined sunscreen product expiration period.

20. The apparatus of claim 1 further including battery interlock logic operative to prevent operation of at least part of the apparatus below a predetermined battery level.

21. An apparatus for managing exposure to the sun, comprising:
means responsive to user interaction for selecting a first activity type,
means for identifying the means for selecting a first activity type,
means responsive to user interaction for selecting a second activity type,
means for identifying the means for selecting a second activity type,
means for timing a first sunshine exposure duration associated with the first activity type,
means for timing a second sunshine exposure duration different from the first sunshine exposure duration and associated with the second activity type, and
means responsive to the first means for timing a first sunshine exposure and to the means for timing a second sunshine exposure, for alerting the user at the end of the first and second durations.

22. A method for managing exposure to the sun, comprising:
providing a vessel for a sunscreen product,
providing a sunscreen product in the vessel having a plurality of sunscreen-product-specific time durations corresponding to sunlight exposure limits for different types of activities,
providing timing logic associated with the vessel and having a predetermined duration corresponding to the sunscreen-product-specific time durations of the sunscreen product in the vessel,
applying the sunscreen to an area of the skin,
starting the timing logic for a first type of activity,
providing a first timing indication from the timing logic for the first type of activity,
again applying the sunscreen to an area of the skin after the step of providing,
starting the timing logic for a second type of activity,
providing a second timing indication from the timing logic for the second type of activity, and
again applying the sunscreen to an area of the skin after the step of providing a second timing indication.

23. The method of claim 22 wherein the steps of starting and providing for a first type of activity are for a terrestrial activity and the steps of starting and providing for a second type of activity are for an aquatic activity.

24. The method of claim 22 wherein the steps of providing a sunscreen product and providing timing logic are performed by different commercial entities.

25. The method of claim 22 further including the step of configuring the timing logic for the sunscreen product provided in the step of providing a sunscreen product.

26. The method of claim 22 wherein the step of providing timing logic includes an end-user selection among different timer models.
